(19) United States
(12) Patent Application Publication
(10) Pub. No.: US 2025/0221047 A1
(43) Pub. Date: Jul. 3, 2025

(54) ARRAY SUBSTRATE, DISPLAY PANEL, AND ELECTRONIC DEVICE

(71) Applicants: Hefei Visionox Technology Co., Ltd., Hefei (CN); KunShan Go-Visionox Opto-Electronics Co., Ltd., Kunshan (CN)

(72) Inventors: Zhiwei ZHOU, Hefei (CN); Jinfang ZHANG, Hefei (CN); Lu ZHANG, Hefei (CN); Jingsha LIU, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/939,563

(22) Filed: Nov. 7, 2024

(30) Foreign Application Priority Data
Jan. 2, 2024 (CN) 202410008546.5
May 8, 2024 (CN) 202410565972.9

(51) Int. Cl. H01L 27/12

(52) U.S. Cl. CPC H10D 86/60; H10D 86/421; H10D 86/441; H10D 86/451

(57) ABSTRACT

Disclosed are an array substrate, a display panel, and an electronic device. Two driving units, adjacent in a first direction, in the array substrate are configured to share a first scan wire and a second scan wire, so that a semiconductor wiring segment in a driving unit may extend along a straight line and overlap with the first scan wire and the second scan wire to form a first switching transistor and a second switching transistor respectively, thereby reducing a space occupied by the semiconductor wiring segment.

### CROSS-REFERENCE TO RELATED APPLICATIONS

This application claims priority to Chinese Patent Application No. 202410008546.5, filed on Jan. 2, 2024, and Chinese Patent Application No. 202410565972.9, filed on May 8, 2024, which are hereby incorporated by reference in their entireties.

### TECHNICAL FIELD

Embodiments of the present disclosure relate to the field of display technologies, and in particular, to an array substrate, a display panel, and an electronic device.

### BACKGROUND

As for some display panels, in order to achieve under screen camera or under screen optical fingerprint recognition in a full screen, a light-transmitting display area may be provided in the display panel. External light can enter an optical acquisition device below the display panel through the light-transmitting display area with a display function being satisfied. However, as the increase of the pixels per inch (PPI), wiring in an array substrate of the display panel becomes denser, resulting in reduction of an area for light transmission in the array substrate, thereby affecting overall transmittance of the display panel.

### SUMMARY

To overcome the shortcomings mentioned above, the present disclosure aims to provide an array substrate, including:
a substrate;
a first semiconductor layer located on a side of the substrate, where the first semiconductor layer includes a first semiconductor wiring segment and a second semiconductor wiring segment, and the first semiconductor wiring segment and the second semiconductor wiring segment extend side by side in a first direction;
a first conductive layer located on a side, away from the substrate, of the first semiconductor layer, where the first conductive layer includes a first scan wire and a second scan wire, the first scan wire and the second scan wire extend side by side in a second direction, and the first direction intersects with the second direction;
a plurality of driving units, where the plurality of driving units include a first driving unit and a second driving unit adjacent in the first direction;
in the first direction, the first driving unit is located on a side, away from the second scan wire, of the first scan wire, and the second driving unit is located on a side, away from the first scan wire, of the second scan wire;
the first driving unit includes a first switching transistor and a second switching transistor; an orthographic projection of the first semiconductor wiring segment on the substrate at least partially overlaps with orthographic projections of the first scan wire and the second scan wire on the substrate separately, the first switching transistor and the second switching transistor of the first driving unit are respectively located at a position of the orthographic projection of the first semiconductor wiring segment on the substrate overlapping with the orthographic projection of the first scan wire on the substrate, and a position of the orthographic projection of the first semiconductor wiring segment on the substrate overlapping with the orthographic projection of the second scan wire on the substrate; and
the second driving unit includes a first switching transistor and a second switching transistor; an orthographic projection of the second semiconductor wiring segment on the substrate at least partially overlaps with the orthographic projections of the first scan wire and the second scan wire on the substrate separately, the first switching transistor and the second switching transistor of the second driving unit are respectively located at a position of the orthographic projection of the second semiconductor wiring segment on the substrate overlapping with the orthographic projection of the first scan wire on the substrate, and a position of the orthographic projection of the second semiconductor wiring segment on the substrate overlapping with the orthographic projection of the second scan wire on the substrate.

The present disclosure further provides a display panel, and the display panel includes the array substrate provided by the present disclosure.

The present disclosure further provides an electronic device, and the electronic device includes the display panel provided by the present disclosure.

The present disclosure has the following beneficial effects.

According to the array substrate, the display panel, and the electronic device provided by the present disclosure, two driving units, adjacent in the first direction, in the array substrate are configured to share the first scan wire and the second scan wire, so that the semiconductor wiring segment in the driving unit may extend along a straight line and overlap with the first scan wire and the second scan wire to form a first switching transistor and a second switching transistor respectively, thereby reducing a space occupied by the semiconductor wiring segment.

### BRIEF DESCRIPTION OF THE DRAWINGS

To more clearly explain the technical solutions in the embodiments of the present disclosure, accompanying drawings used in the embodiments will be briefly introduced. It should be understood that the following accompanying drawings only show certain embodiments of the present disclosure, and therefore should not be regarded as limitation on a scope. For those skilled in the art, other relevant accompanying drawings may also be obtained based on these drawings without creative efforts.

FIG. 1 is a schematic structural diagram of film layers of an array substrate according to an embodiment of the present disclosure.

FIG. 2 is a perspective schematic diagram of film layers of an array substrate according to another embodiment of the present disclosure.

FIG. 3 is a perspective schematic diagram of film layers of an array substrate according to still another embodiment of the present disclosure.

FIG. 4 is a perspective schematic diagram of film layers of an array substrate according to yet still another embodiment of the present disclosure.

FIG. 5 is a perspective schematic diagram of film layers of an array substrate according to yet still another embodiment of the present disclosure.

FIG. 6 is a schematic diagram of a circuit of a driving unit according to an embodiment of the present disclosure.

FIG. 7 is a perspective schematic diagram of film layers of an array substrate according to yet still another embodiment of the present disclosure.

FIG. 8 is a perspective schematic diagram of film layers of an array substrate according to yet still another embodiment of the present disclosure.

FIG. 9 is a perspective schematic diagram of film layers of an array substrate according to yet still another embodiment of the present disclosure.

FIG. 10 is a perspective schematic diagram of film layers of an array substrate according to yet still another embodiment of the present disclosure.

FIG. 11 is a perspective schematic diagram of film layers of an array substrate according to yet still another embodiment of the present disclosure.

FIG. 12 is a perspective schematic diagram of film layers of an array substrate according to yet still another embodiment of the present disclosure.

FIG. 13 is a perspective schematic diagram of film layers of an array substrate according to yet still another embodiment of the present disclosure.

FIG. 14 is a perspective schematic diagram of film layers of an array substrate according to yet still another embodiment of the present disclosure.

FIG. 15 is a perspective schematic diagram of film layers of an array substrate according to yet still another embodiment of the present disclosure.

FIG. 16 is a perspective schematic diagram of film layers of an array substrate according to yet still another embodiment of the present disclosure.

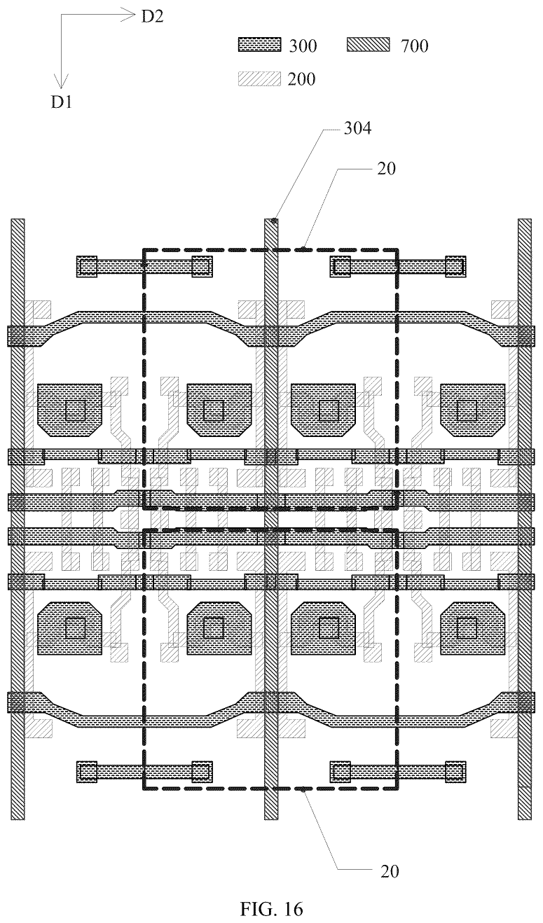

FIG. 17 is a perspective schematic diagram of film layers of an array substrate according to yet still another embodiment of the present disclosure.

FIG. 18 is a perspective schematic diagram of film layers of an array substrate according to yet still another embodiment of the present disclosure.

FIG. 19 is a perspective schematic diagram of film layers of an array substrate according to yet still another embodiment of the present disclosure.

FIG. 20 is a perspective schematic diagram of film layers of an array substrate according to yet still another embodiment of the present disclosure.

FIG. 21 is a perspective schematic diagram of film layers of an array substrate according to yet still another embodiment of the present disclosure.

FIG. 22 is a perspective schematic diagram of film layers of an array substrate according to yet still another embodiment of the present disclosure.

### DETAILED DESCRIPTION OF THE EMBODIMENTS

To make purposes, technical solutions, and advantages of the embodiments of the present disclosure clearer, the technical solutions in embodiments of the present disclosure will be clearly and completely described with reference to accompanying drawings corresponding to the embodiments of the present disclosure in the following description. Apparently, the described embodiments are only some, not all, embodiments of the present disclosure. Generally, components of the embodiments of the present disclosure described and shown in the accompanying drawings may be arranged and designed in various configurations.

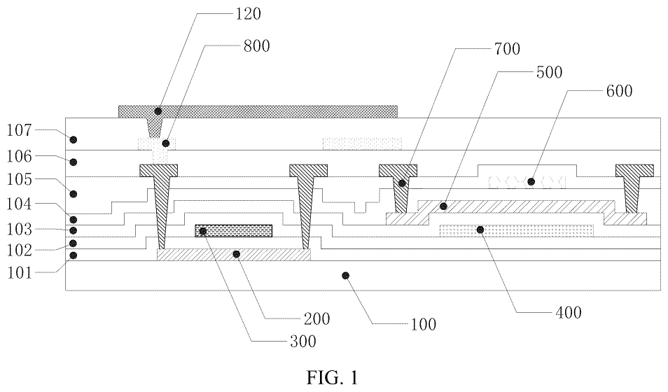

Referring to FIG. 1, FIG. 1 is a cross-sectional view of an array substrate according to an embodiment of the present disclosure. The array substrate may include a substrate 100, a first semiconductor layer 200 located on a side of the substrate 100, and a first conductive layer 300 located on a side, away from the substrate 100, of the first semiconductor layer 200.

In this embodiment, a first insulation layer 101 may also be provided between the first semiconductor layer 200 and the first conductive layer 300.

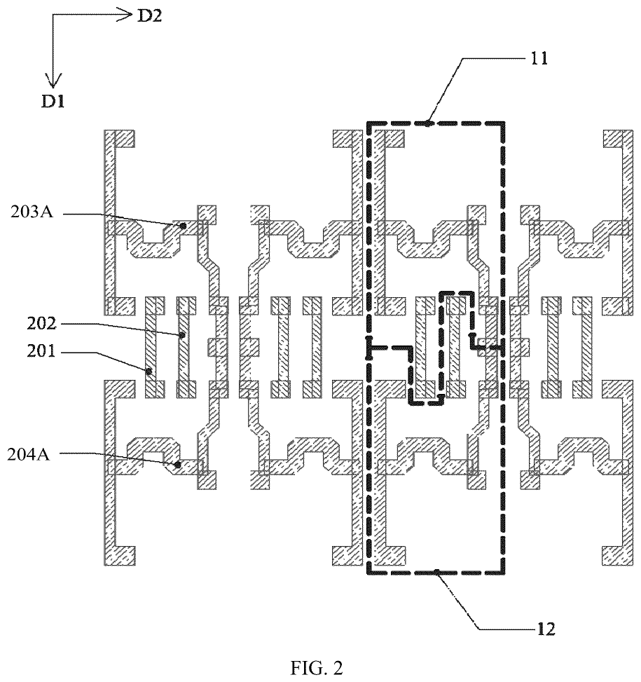

Referring to FIG. 2, the first semiconductor layer 200 may include a plurality of semiconductor wiring segments, and the plurality of semiconductor wiring segments may include a first semiconductor wiring segment 201 and a second semiconductor wiring segment 202. The first semiconductor wiring segment 201 and the second semiconductor wiring segment 202 extend side by side in a first direction D1.

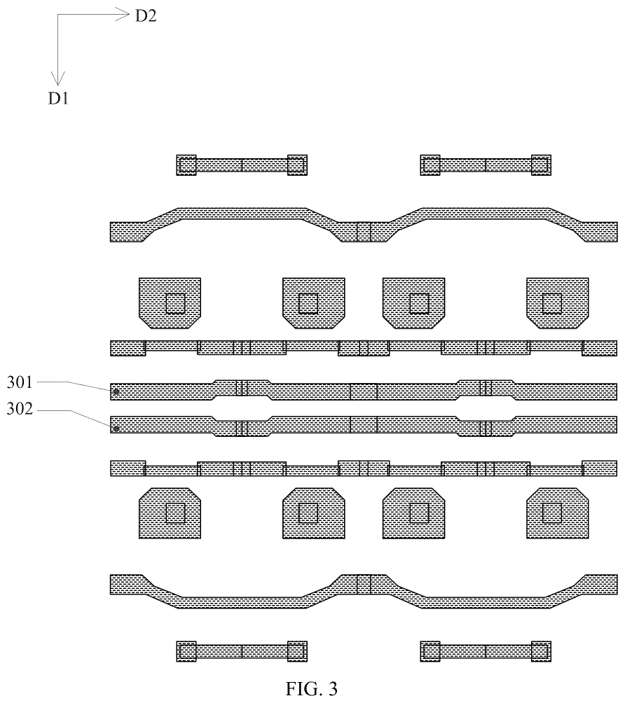

Referring to FIG. 3, the first conductive layer 300 may include a plurality of wires. Exemplarily, it may include a first scan wire 301 and a second scan wire 302, where the first scan wire 301 and the second scan wire 302 extend side by side in a second direction D2 and synchronously transmit a same scan signal. The first direction D1 intersects with the second direction D2, for example, the first direction D1 is perpendicular to the second direction D2.

Optionally, in an example, the material of the first conductive layer 300 may include a metal material, and the first scan wire 301 and the second scan wire 302 may be metal wires.

In another example, the material of the first conductive layer 300 may further include a non-metallic material, such as a metal oxide (i.e., indium tin oxide), graphene, a conductive semiconductor material, and so on.

In this embodiment, a plurality of film layers of the array substrate cooperate with each other to form a plurality of Thin Film Transistors (TFTs) at different positions. The plurality of TFTs cooperate with each other to form a plurality of driving units. The driving units are configured to drive pixels to emit light. And a driving unit may include a plurality of different transistors.

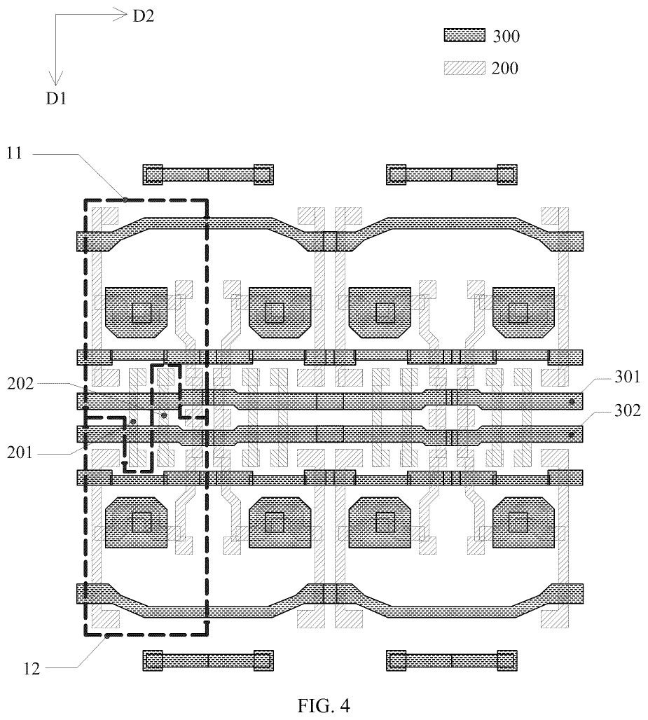

Referring to FIG. 4, as shown in the rectangular dashed box in FIG. 4, a plurality of driving units of an array substrate may include a first driving unit 11 and a second driving unit 12 adjacent in the first direction D1.

In the first direction D1, the first driving unit 11 is located on a side, away from the second scan wire 302, of the first scan wire 301, and the second driving unit 12 is located on a side, away from the first scan wire 301, of the second scan wire 302.

Exemplarily, considering the first scan wire 301 and the second scan wire 302 as a whole, the first driving unit 11 and the second driving unit 12 are located on different sides of the first scan wire 301 and the second scan wire 302 in the first direction D1.

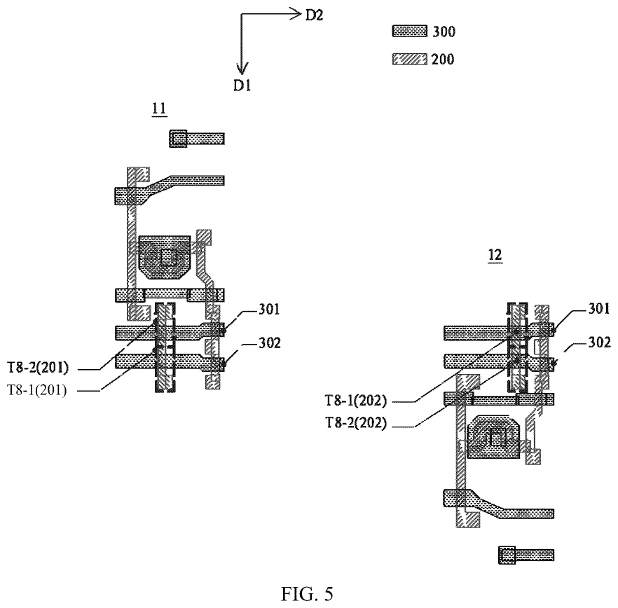

Referring to FIG. 5, an orthographic projection of the first semiconductor wiring segment 201 on the substrate 100 at least partially overlaps with orthographic projections of the first scan wire 301 and the second scan wire 302 on the substrate 100 separately. A first switching transistor T8-1 and a second switching transistor T8-2 of the first driving unit 11 are respectively located at a position where the orthographic projection of the first semiconductor wiring segment 201 overlaps with the orthographic projection of the first scan wire 301, and a position where the orthographic projection of the first semiconductor wiring segment 201 overlaps with the orthographic projection of the second scan wire 302.

An orthographic projection of the second semiconductor wiring segment 202 on the substrate 100 at least partially overlaps with the orthographic projections of the second scan wire 302 and the first scan wire 301 on the substrate 100 separately. A first switching transistor T8-1 and a second switching transistor T8-2 of the second driving unit 12 are respectively located at a position where the orthographic projection of the first semiconductor wiring segment 202 overlaps with the orthographic projection of the first scan wire 301, and a position where the orthographic projection of the first semiconductor wiring segment 202 overlaps with the orthographic projection of the second scan wire 302.

Exemplarily, the first semiconductor wiring segment 201 belongs to the first driving unit 11. The first semiconductor wiring segment 201 extending in the first direction D1 separately overlaps with the first scan wire 301 and the second scan wire 302 extending in the second direction D2, and the overlapping positions respectively correspond to the first switching transistor T8-1 and the second switching transistor T8-2 of the first driving unit 11.

The second semiconductor wiring segment 202 belongs to the second driving unit 12. The second semiconductor wiring segment 202 extending in the first direction D1 separately overlaps with the first scan wire 301 and the second scan wire 302 extending in the second direction D2, and the overlapping positions respectively correspond to the first switching transistor T8-1 and the second switching transistor T8-2 of the second driving unit 12.

Based on the design mentioned above, according to the array substrate provided by the embodiment, two scan wires (i.e., the first scan wire 301 and the second scan wire 302) are provided between the first driving unit 11 and the second driving unit 12 adjacent in the first direction D1 and configured to transmit the same signal. Meanwhile, the first driving unit 11 and the second driving unit 12 share the first scan wire 301 and the second scan wire 302. Therefore, for the first switching transistor T8-1 and the second switching transistor T8-2 that need to be set in series and require the same gate control signal, a semiconductor wiring segment extending along a straight line may be used for separately overlapping with the first scan wire 301 and the second scan wire 302 to form transistors. Compared to a U-shaped semiconductor wiring segment which is designed to overlap with the same scan wire twice in a traditional solution, the solution provided by the present embodiment may save more wiring space and thus be more conducive to improving transmittance or pixels per inch (PPI) of the array substrate.

Optionally, referring back to FIG. 1, in some possible implementations, the array substrate may further include a second conductive layer 400, a second semiconductor layer 500, a third conductive layer 600, a fourth conductive layer 700, and a fifth conductive layer 800 located on a side, away from the substrate 100, of the first conductive layer 300 sequentially.

Optionally, the array substrate may further include an insulation layer located between adjacent film layers, such as a first insulation layer 101 (i.e., a first gate insulation layer) between the first semiconductor layer 200 and the first conductive layer 300, a second insulation layer 102 (i.e., a capacitive dielectric layer) between the first conductive layer 300 and the second conductive layer 400, a third insulation layer 103 (i.e., a buffer layer) between the second conductive layer 400 and the second semiconductor layer 500, a fourth insulation layer 104 (i.e., a second gate insulation layer) between the second semiconductor layer 500 and the third conductive layer 600, a fifth insulation layer 105 (i.e., an interlayer insulation layer) between the third conductive layer 600 and the fourth conductive layer 700, and a sixth insulation layer 106 (i.e., a first planarization layer) between the fourth conductive layer 700 and the fifth conductive layer 800.

Optionally, in an example, the material of the second conductive layer 400 may include a metal material, and/or the material of the third conductive layer 600 may include a metal material, and/or the material of the fourth conductive layer 700 may include a metal material, and/or the material of the fifth conductive layer 800 may include a metal material.

In another example, the material of the third conductive layer 600 may further include a non-metallic material, and/or the material of the third conductive layer 600 may include a non-metallic material, and/or the material of the fourth conductive layer 700 may include a non-metallic material, and/or the material of the fifth conductive layer 800 may include a non-metallic material, such as a metal oxide (i.e., indium tin oxide), a graphene, a conductive semiconductor material, and so on.

Optionally, the array substrate may further include a sixth conductive layer located on a side, away from the substrate, of the fifth conductive layer 800, and a seventh insulation layer 107 (i.e., second planarization layer) located between the fifth conductive layer 800 and the sixth conductive layer.

In some possible implementations, referring to FIG. 2 and FIG. 4, the first semiconductor layer 200 may further includes a third semiconductor wiring segment 203A corresponding to other transistors in the first driving unit 11 except for the first switching transistor T8-1 and the second switching transistor T8-2 of the first driving unit 11, and a fourth semiconductor wiring segment 204A corresponding to other transistors in the second driving unit 12 except for the first switching transistor T8-1 and the second switching transistor T8-2 of the second driving unit 12.

The third semiconductor wiring segment 203A and the fourth semiconductor wiring segment 204A are symmetrically disposed relative to an axis extending in the second direction D2, and an orthographic projection of the axis on the substrate 100 is located between the orthographic projections of the first scan wire 301 and the second scan wire 302 on the substrate 100.

Exemplarily, in the present embodiment, in addition to the first switching transistor T8-1 and the second switching transistor T8-2, the other transistors in the first driving unit 11 and the other transistors in the second driving unit 12 may be symmetrically distributed in the first direction D1. Thus, the first driving unit 11 and the second driving unit 12 may also share other wires extending in the second direction D2, thereby saving more wiring space, and ensuring the layout consistency of the switch transistor, thus reducing the risk of uneven display.

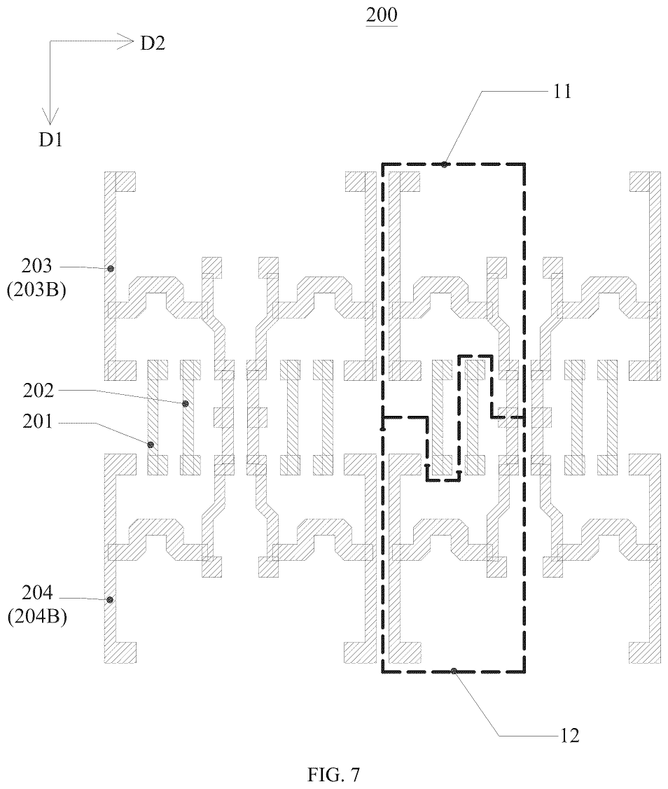

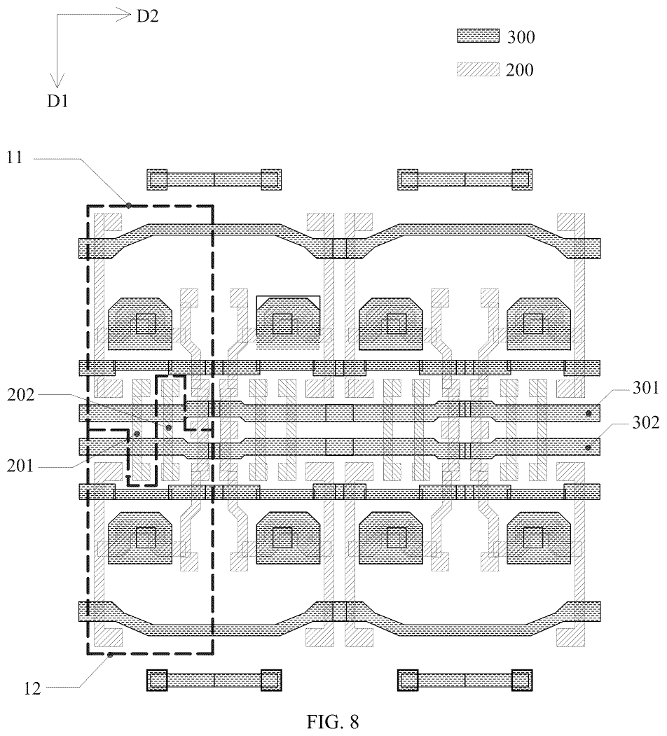

In some possible implementations, the driving unit may include a driving transistor T1. As shown in FIG. 7 or FIG. 8, the first semiconductor layer 200 may further includes a third semiconductor wiring segment 203B, corresponding to other transistors in the first driving unit 11 except for the first switching transistor T8-1, the second switching transistor T8-2 and the driving transistor T1 of the first driving unit 11, and a fourth semiconductor wiring segment 204B corresponding to other transistors in the second driving unit 12 except for the first switching transistor T8-1, the second switching transistor T8-2 and the driving transistor T1 of the second driving unit 12.

The third semiconductor wiring segment 203B and the fourth semiconductor wiring segment 204B are symmetrically disposed relative to an axis extending in the second direction D2, and an orthographic projection of the axis on the substrate 100 is located between the orthographic projections of the first scan wire 301 and the second scan wire 302 on the substrate 100.

Exemplarily, in the present embodiment, in addition to the first switching transistor T8-1, the second switching transistor T8-2 and the driving transistor T1, the other transistors in the first driving unit 11 and the other transistors in the second driving unit 12 may be symmetrically distributed in the first direction D1.

The semiconductor wiring segment corresponding to the driving transistor T1 is asymmetrically disposed along the axis extending in the second direction D2. That is, the driving transistor T1 is asymmetrically distributed in the first direction D1.

In this way, the first driving unit 11 and the second driving unit 12 may also share other wires extending in the second direction D2, thereby saving more wiring space, and ensuring the layout consistency of the switch transistor, thus reducing the risk of uneven display.

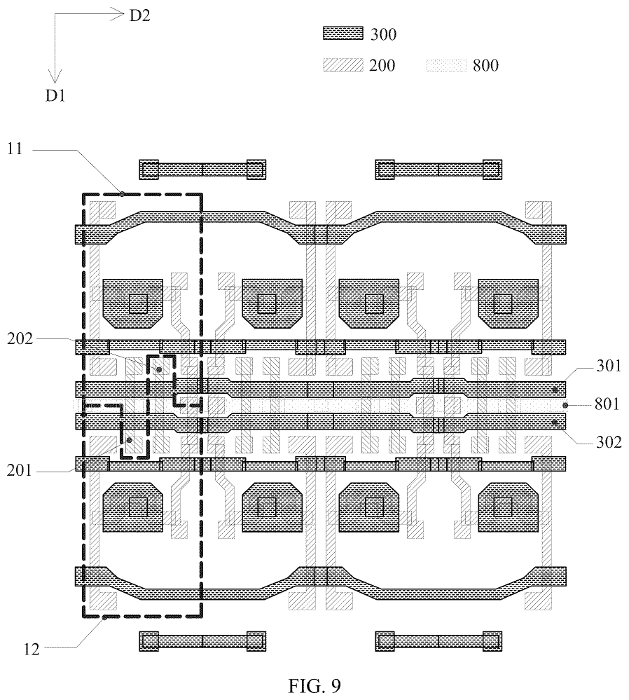

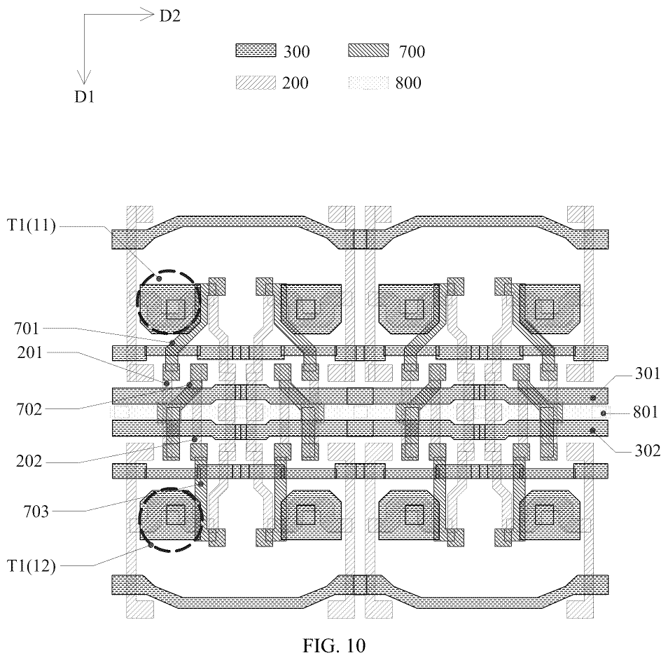

In some possible implementations, as shown in FIG. 9 and FIG. 10, the array substrate may further include a first initialization wire 801 extending in the second direction D2. An orthographic projection of the first initialization wire 801 on the substrate 100 is located between the orthographic projections of the first scan wire 301 and the second scan wire 302 on the substrate 100.

The driving unit includes a driving transistor T1, the driving transistor T1 includes a first electrode, a second electrode, and a gate electrode. The first driving unit 11 and the second driving unit 12 share the first initialization wire 801, and the first initialization wire 801 is configured to provide first initialization voltage for a first electrode of a driving transistor T1 of the first driving unit 11 and a drain of a driving transistor T1 of the second driving unit 12. The first electrode and the second electrode may respectively be the source and the drain of the driving transistor T1.

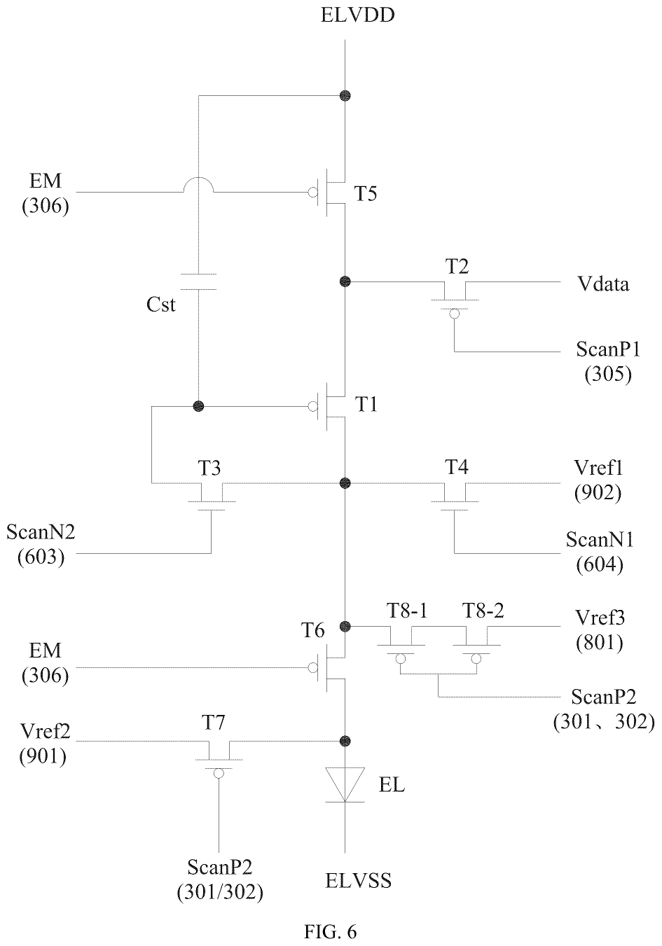

Exemplarily, referring to FIG. 6 and FIG. 9, an 8T1C driving circuit may be applied for the driving unit provided by the present embodiment. A core component of the driving unit may include a driving transistor T1. The driving transistor T1 of the first driving unit 11 is located on a side, away from the second scan wire 302, of the first scan wire 301, and the driving transistor T1 of the second driving unit 12 is located on a side, away from the first scan wire 301, of the second scan wire 302.

During a display process, to improve the display effect, it is necessary to initialize first electrode voltage of the driving transistor T1 at a specific time point. Therefore, it is necessary to arrange a wire in the array substrate for transmitting a first initialization voltage Vref3 (that is, the first initialization wire 801).

In this case, referring to FIG. 9, other transistors in the first driving unit 11 and the second driving unit 12 provided by the present embodiment are symmetrically disposed in the first direction D1, besides the first switching transistor T8-1 and the second switching transistor T8-2. Therefore, the first initialization wire 801 may be disposed at a position where an orthographic projection of the first initialization wire 801 on the substrate 100 is located between the orthographic projections of the first scan wire 301 and the second scan wire 302 on the substrate 100. Thus, the first driving unit 11 and the second driving unit 12 may share the first initialization wire 801, thereby reducing a quantity of wires and saving wiring space.

In some possible implementations, referring back to FIG. 6 and FIG. 9, the first switching transistor T8-1 and the second switching transistor T8-2 are connected in series between the first electrode of the driving transistor T1 and the first initialization wire 801. The first switching transistor T8-1 and the second switching transistor T8-2 are configured to provide voltage initialization control on the first electrode of the driving transistor T1.

That is, the gates of the first switching transistor T8-1 and the second switching transistor T8-2 are respectively formed by the first scan wire 301 and the second scan wire 302. When a first scan signal ScanP2 is synchronously transmitted by the first scan wire 301 and the second scan wire 302, the first switching transistor T8-1 and the second switching transistor T8-2 may be simultaneously controlled to turn on or off electrical connection between the first electrode of the driving transistor T1 and the first initialization wire 801, thereby achieving voltage initialization control on the first electrode of the driving transistor T1.

Specifically, the first initialization wire 801 may be located in the fifth conductive layer 800.

Furthermore, referring to FIG. 1 and FIG. 10, the driving transistor T1 of the first driving unit 11 is located on a side, away from the second scan wire 302, of the first scan wire 301, and the driving transistor T1 of the second driving unit 12 is located on a side, away from the first scan wire 301, of the second scan wire 302.

The fourth conductive layer 700 includes a first connection wiring segment 701, a second connection wiring segment 702, and a third connection wiring segment 703. An end, close to the first scan wire 301, of the first semiconductor wiring segment 201 is connected to the first electrode of the driving transistor T1 of the first driving unit 11 through the first connection wiring segment 701. An end, close to the second scan wire 302, of the first semiconductor wiring segment 201 is connected to the first initialization wire 801 through the second connection wiring segment 702.

An end, close to the second scan wire 302, of the second semiconductor wiring segment 202 is connected to the first electrode of the driving transistor T1 of the second driving unit 12 through the third connection wiring segment 703. An end, close to the first scan wire 301, of the second semiconductor wiring segment 202 is connected to the first initialization wire 801 through the second connection wiring segment 702.

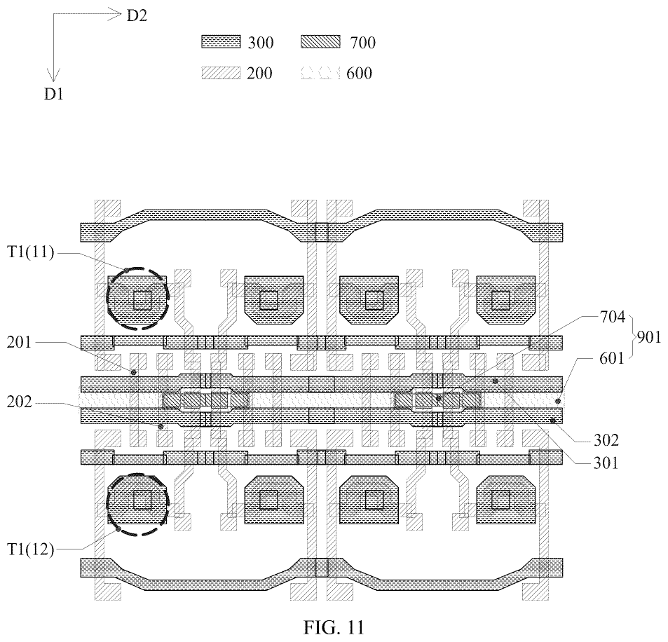

In some possible implementations, the array substrate may further include a second initialization wire 901 extending in the second direction D2. Referring to FIG. 11, an orthographic projection of the second initialization wire 901 on the substrate 100 is located between the orthographic projections of the first scan wire 301 and the second scan wire 302 on the substrate 100. Exemplarily, the second initialization wire 901 and the first initialization wire 801 may be located on different film layers, and the orthographic projection of the second initialization wire 901 on the substrate 100 may at least partially overlap with the orthographic projection of the first initialization wire 801 on the substrate 100

Referring back to FIG. 1, the driving unit may include a pixel electrode connection point 120. The pixel electrode connection point 120 is configured to electrically connect with an anode of a light-emitting sub-pixel to transmit a driving signal to the anode. The first driving unit 11 and the second driving unit 12 share a second initialization wire 901. The second initialization wire 901 is configured to provide the second initialization voltage Vref2 shown in FIG. 6 for the pixel electrode connection points 120 of the first driving unit 11 and the second driving unit 12. That is, the second initialization wire 901 is configured to provide the second initialization voltage Vref2 for the anode.

The first driving unit 11 and the second driving unit 12 provided by the present embodiment are generally symmetrically disposed in the first direction D1. Therefore, the second initialization wire 901 may be arranged at a position where an orthographic projection of the second initialization wire 901 on the substrate 100 is located between the orthographic projections of the first scan wire 301 and the second scan wire 302 on the substrate 100. Thus, the first driving unit 11 and the second driving unit 12 may share the second initialization wire 901, thereby reducing a quantity of wires and saving wiring space.

Furthermore, in some possible implementations, referring back to FIG. 11, the second initialization wire 901 includes a first portion 601 and a second portion 704. The first portion 601 is located in the third conductive layer 600, and the second portion 704 is located in the fourth conductive layer 700. The first portion 601 and the second portion 704 are alternately disposed in the second direction D2 to avoid other wires, extending in the first direction D1, of the same layer. The first portion 601 and the second portion 704 may be electrically connected to each other through a through-hole running through a part of insulation layers of the array substrate.

In some possible implementations, the driving unit may include a third switching transistor T7. Referring back to FIG. 6 again, the third switching transistor T7 is connected to the pixel electrode connection point 120 and the second initialization wire 901 respectively, and the third switching transistor T7 is configured to provide voltage initialization control on the pixel electrode connection point 120.

Specifically, a third switching transistor T7 of the first driving unit 11 may be formed by overlapping between the third semiconductor wiring segment 203 and the first scan wire 301 in the first driving unit 11, and a third switching transistor T7 of the second driving unit 12 may be formed by overlapping between the fourth semiconductor wiring segment 204 and the second scan wire 302 in the second driving unit 12. A signal transmitted by the first scan wire 301 or the second scan wire 302 may control the third switching transistor T7 to turn on or off electrical connection between the pixel electrode connection point 120 and the second initialization wire 901, thereby achieving voltage initialization control on the pixel electrode connection point 120.

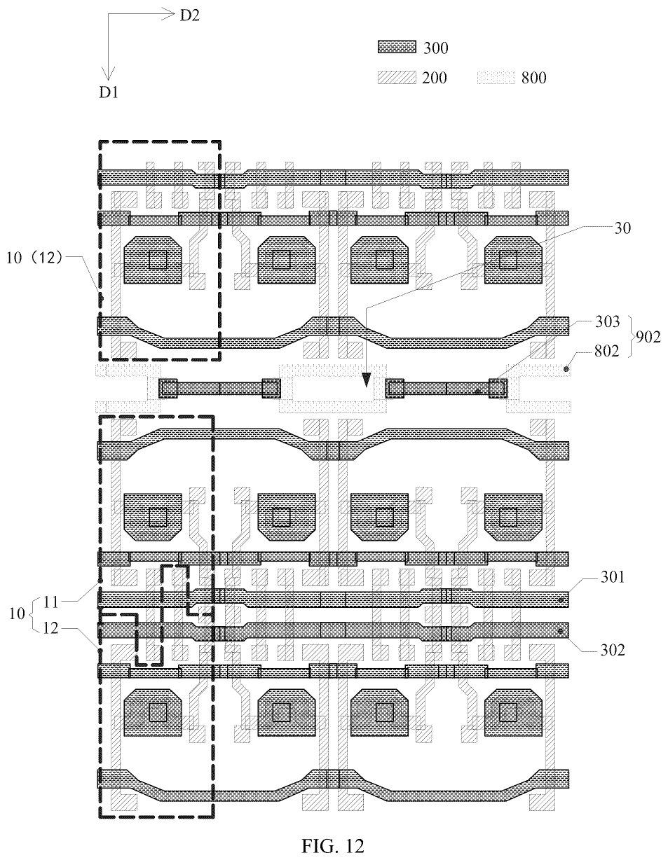

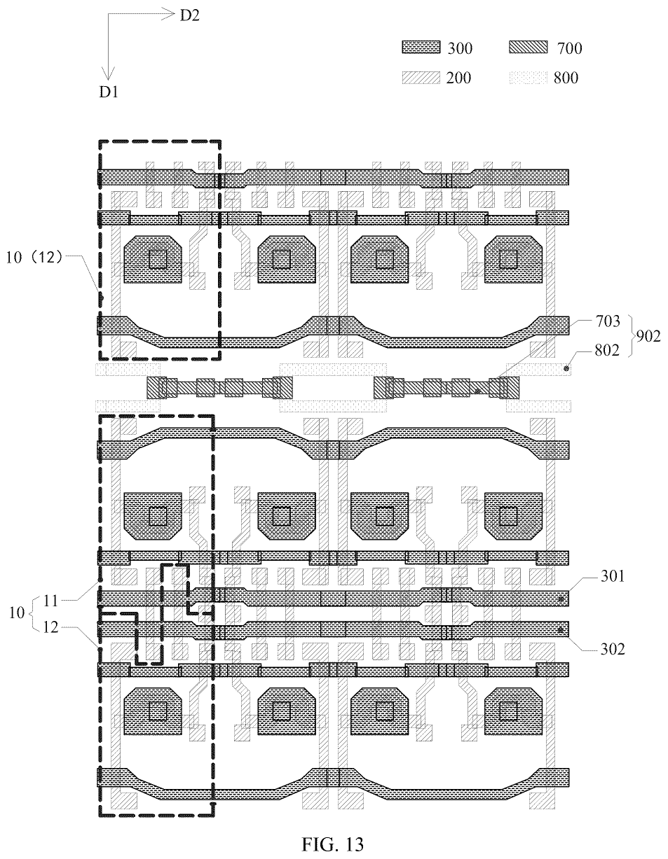

In some possible implementations, referring to FIG. 12 or FIG. 13, the array substrate may include a plurality of first driving unit groups 10, and each of the plurality of first driving unit groups 10 includes a first driving unit 11 and a second driving unit 12. The first driving unit 11 and the second driving unit 12 in a same first driving unit group 10 share the first scan wire 301 and the second scan wire 302.

The array substrate may further include a third initialization wire 902. In the first direction D1, an orthographic projection of the third initialization wire 902 on the substrate 100 is located between orthographic projections of two adjacent first driving unit groups 10 on the substrate 100. A first driving unit 11 and a second driving unit 12, which are adjacent in the first direction D1 and respectively belong to different first driving unit groups 10, share the third initialization wire 902, thereby reducing a quantity of wires and saving wiring space. The third initialization wire 902 is configured to provide the third initialization voltage Vref1 shown in FIG. 6 for a gate of the driving transistor T1.

In some possible implementations, referring back to FIG. 12 or 13, the third initialization wire 902 may include a third portion and a fourth portion 802. The third portion is located in at least one of: the first conductive layer 300 and the fourth conductive layer 700, the fourth portion 802 is located in the fifth conductive layer 800, and the third portion and the fourth portion 802 are alternately disposed in the second direction D2. The fourth portion 802 includes a light-transmitting hollow region 30.

Exemplarily, the third portion includes a first extension portion 303 located in the first conductive layer 300 or a second extension portion 705 located in the fourth conductive layer 700.

Alternatively, the third portion may include both the first extension portion 303 and the second extension portion 705, and an orthographic projection of the first extension portion 303 on the substrate 100 at least partially overlaps with an orthographic projection of the second extension portion 705 on the substrate 100, so that the resistance of the third portion may be reduced, thereby reducing overall resistance of the third initialization wire 902.

The third portion and fourth portion 802 both extend in the second direction D2 and are alternately disposed to constitute the third initialization wire 902. The third portion and fourth portion 802 are electrically connected through a through-hole penetrating through at least a part of insulation layers between conductive layers.

Therein, the fourth portion 802 extending in the fifth conductive layer 800 may be provided with a hollow region 30, and an orthographic projection of the hollow region 30 on the substrate 100 at least partially staggers with orthographic projections of the wires located in other film layers on the substrate 100. Thus, a light-transmitting region may be formed by the hollow region 30 to improve light transmittance of the array substrate.

In some possible implementations, referring back to FIG. 6, the driving unit may include a fourth switching transistor T3 and a fifth switching transistor T4. The fourth switching transistor T3 and the fifth switching transistor T4 are connected between the gate of the driving transistor T1 and the third initialization wire 902. The fourth switching transistor T3 and the fifth switching transistor T4 are configured to provide voltage initialization control on the gate of the driving transistor T1.

Exemplarily, referring to FIG. 12, the fourth switching transistor T3 may be formed by cooperation between the third scan wire 603 in the third conductive layer 600 and the fifth semiconductor wiring segment 501 in the second semiconductor layer 500. The fifth switching transistor T4 may be formed by cooperation between the fourth scan wire 604 in the third conductive layer 600 and the sixth semiconductor wiring segment 502 in the second semiconductor layer 500.

A second scan signal ScanN2 transmitted by the third scan wire 603 and a third scan signal ScanN1 transmitted by the fourth scan wire 604 may control the fourth switching transistor T3 and the fifth switching transistor T4 to turn on or off the electrical connection between the gate of the driving transistor T1 and the third initialization wire 902, thereby achieving voltage initialization control on the gate of the pixel electrode connection point 120.

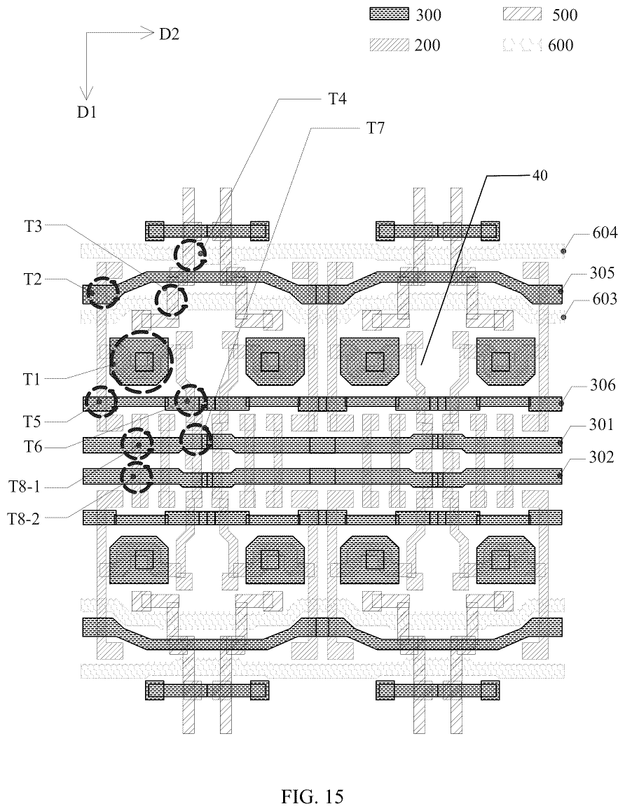

In some possible implementations, referring to FIG. 6 and FIG. 15, the array substrate may include a first scan wire 301 for transmitting the first scan signal ScanP2, a second scan wire 302 for transmitting the first scan signal ScanP2, a third scan wire 603 for transmitting the second scan signal ScanN2, a fourth scan wire 604 for transmitting the third scan signal ScanN1, a fifth scan wire 305 for transmitting a fourth scan signal ScanP1, and a light-emitting control wire 306 for transmitting a light-emitting control signal EM. The first scan wire 301, the second scan wire 302, the fifth scan wire 305, and the light-emitting control wire 306 are located in the first conductive layer 300, and the third scan wire 603 and the fourth scan wire 604 are located in the third conductive layer 600.

The driving unit may include a driving transistor T1, an eighth switching transistor T2, a fourth switching transistor T3, a fifth switching transistor T4, a sixth switching transistor T5, a seventh switching transistor T6, a third switching transistor T7, a first switching transistor T8-1, and a second switching transistor T8-2.

Therein, the driving transistor T1 may be formed by cooperation between the semiconductor wiring segment in the first semiconductor layer 200 and a gate electrode in the first conductive layer 300.

The eighth switching transistor T2 is formed by cooperation between the fifth scan wire 305 and a semiconductor wiring segments in the first semiconductor layer 200. And the eighth switching transistor T2 is configured to perform data write control on a capacitor Cst in the driving unit based on the fourth scan signal ScanP1 transmitted by the fifth scan wire 305.

The fourth switching transistor T3 is formed by the cooperation between the third scan wire 603 in the third conductive layer 600 and semiconductor wiring segments in the second semiconductor layer 500. The fourth switching transistor T3 is configured to perform voltage compensation control on the driving transistor T1 based on the second scan signal ScanN2 transmitted by the third scan wire 603.

The fifth switching transistor T4 is formed by the cooperation between the fourth scan wire 604 in the third conductive layer 600 and semiconductor wiring segments in the second semiconductor layer 500. And the fourth switching transistor T3 and the fifth switching transistor T4 are configured to provide voltage initialization control on the gate of the driving transistor T1 based on the second scan signal ScanN2 transmitted by the third scan wire 603 and the third scan signal ScanN1 transmitted by the fourth scan wire 604 respectively.

The sixth switching transistor T5 and the seventh switching transistor T6 are formed by cooperation between the light-emitting control wire 306 in the first conductive layer 300 and semiconductor wiring segments in the first semiconductor layer 200. And the sixth switching transistor T5 and the seventh switching transistor T6 are configured to perform light-emitting enable control on the driving unit based on the light-emitting control signal EM transmitted by the light-emitting control wire 306.

The third switching transistor T7 is formed by cooperation between either the first scan wire 301 or the second scan wire 302 and semiconductor wiring segments in the first semiconductor layer 200. And the third switching transistor T7 is configured to provide voltage initialization control on the pixel electrode access point of the driving unit based on the first scan signal ScanP2 transmitted by the first scan wire 301 or the second scan wire 302.

The first switching transistor T8-1 and the second switching transistor T8-2 are formed by cooperation between the first scan wire 301 and the second scan wire 302, and the semiconductor wiring segments in the first semiconductor layer 200 respectively. And the first switching transistor T8-1 and the second switching transistor T8-2 are configured to provide voltage initialization control on the first electrode of the driving transistor T1 based on the first scan signal ScanP2 transmitted by the first scan wire 301 and the second scan wire 302 respectively.

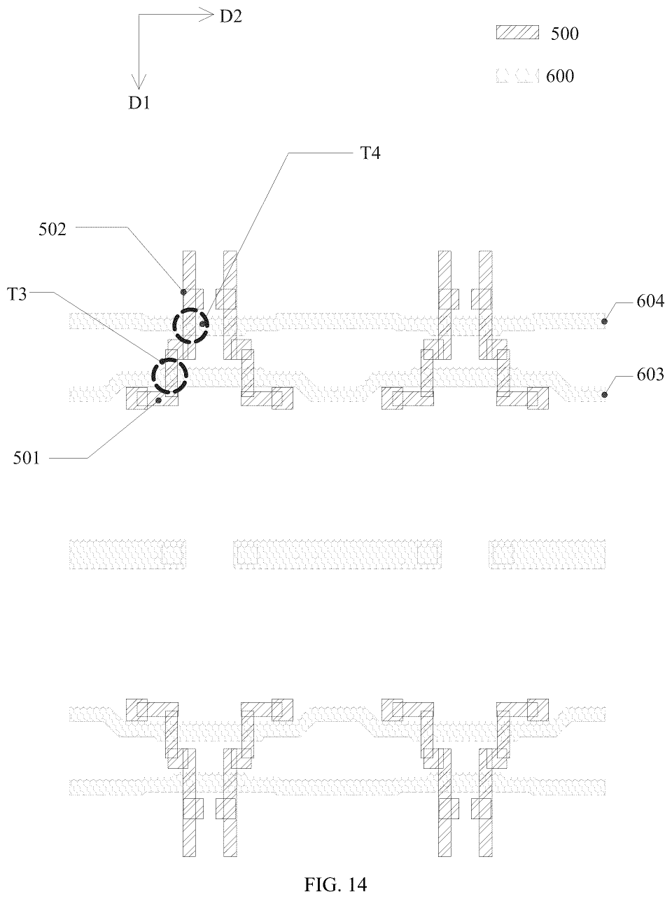

In some possible implementations, referring to FIG. 14, the array substrate may further include a plurality of fourth initialization wires 304 extending in the second direction D2. Optionally, the fourth initialization wire 304 may be located in the fourth conductive layer 700. The fourth initialization wire 304 and the second initialization wire 901 may be electrically connected through a through-hole penetrating through at least one insulation layer, and the fourth initialization wire 304 may intersects with the second initialization wire 901 to form a mesh structure.

The array substrate may include a plurality of second driving unit groups 20, and each of the plurality of second driving unit groups 20 includes two driving units adjacent in the second direction D2. Two driving units in a same second driving unit group 20 are symmetrically disposed relative to the fourth initialization wire 304.

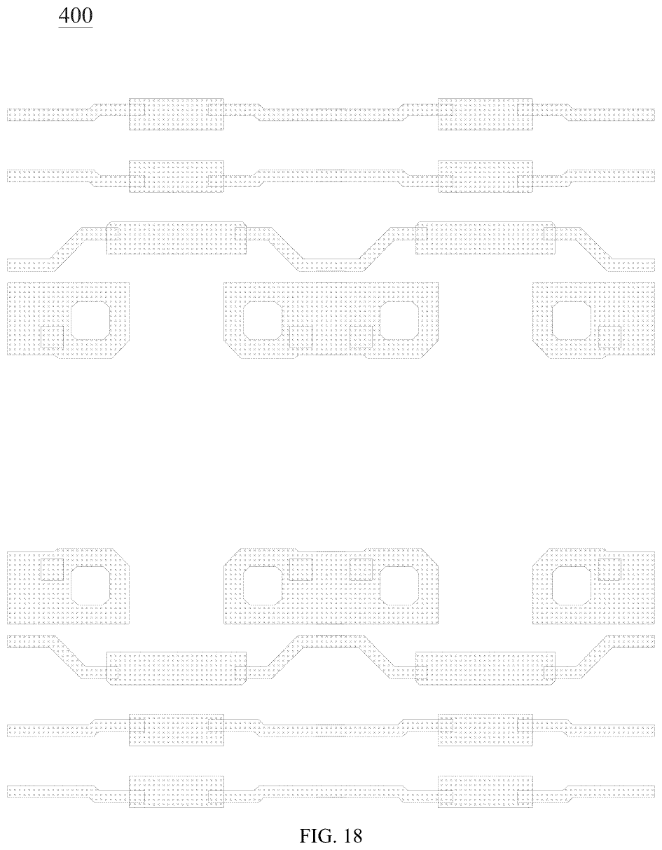

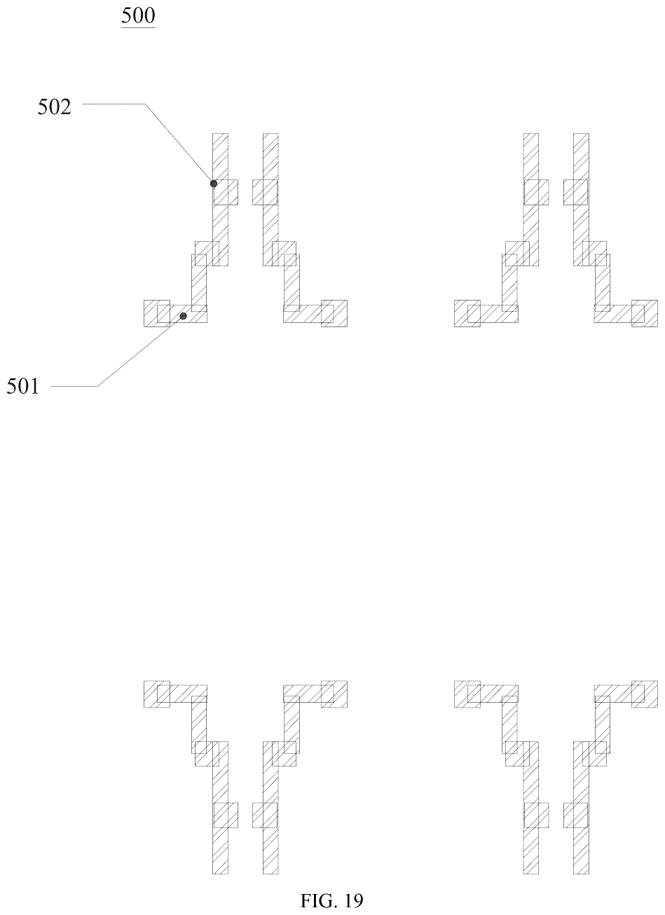

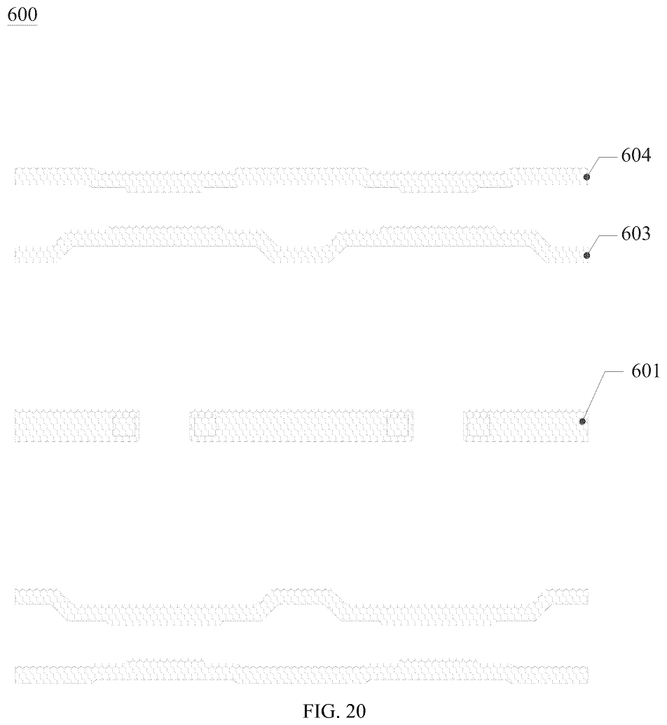

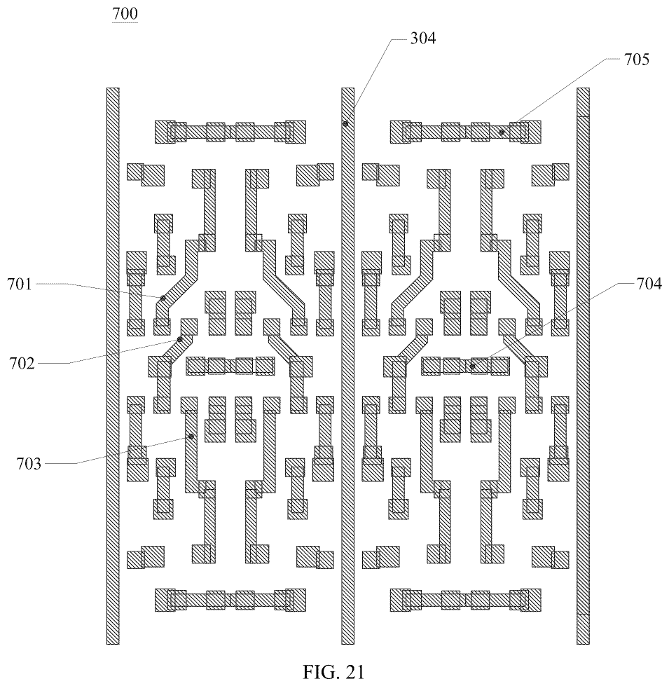

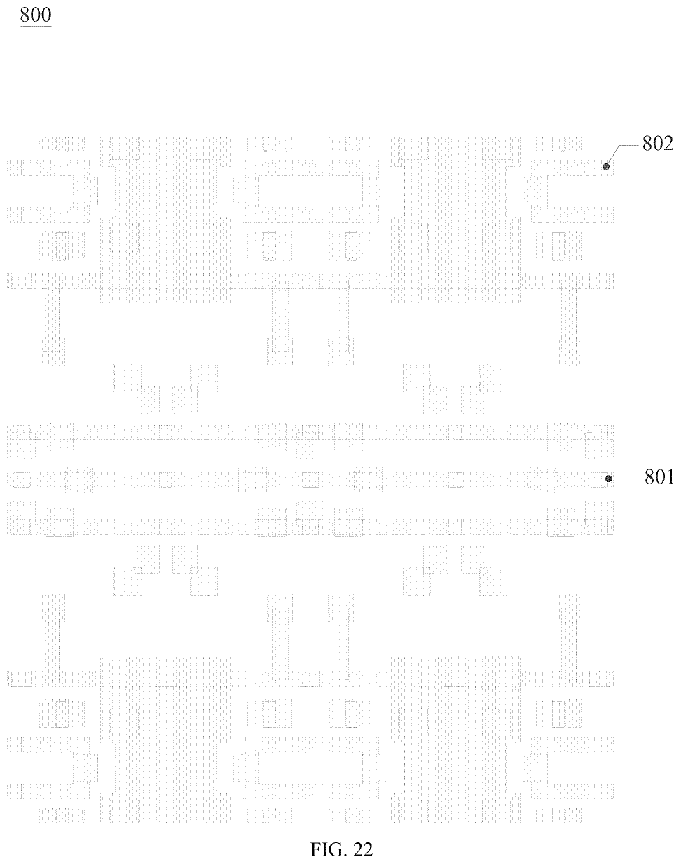

It should be noted that, referring to FIGS. 18 to 22, in addition to the wiring mentioned above, each film layer of the array substrate provided be the present embodiment may further include other more wires or wiring segments. According to the array substrate provided by the present embodiment, the first driving unit 11 and the second driving unit 12 adjacent in the first direction D1 are symmetrically disposed along the first direction D1, so that the first driving unit 11 and the second driving unit 12 may share at least a part of a signal wire or a power wire extending in the second direction D2, thereby saving the wiring space of the array substrate.

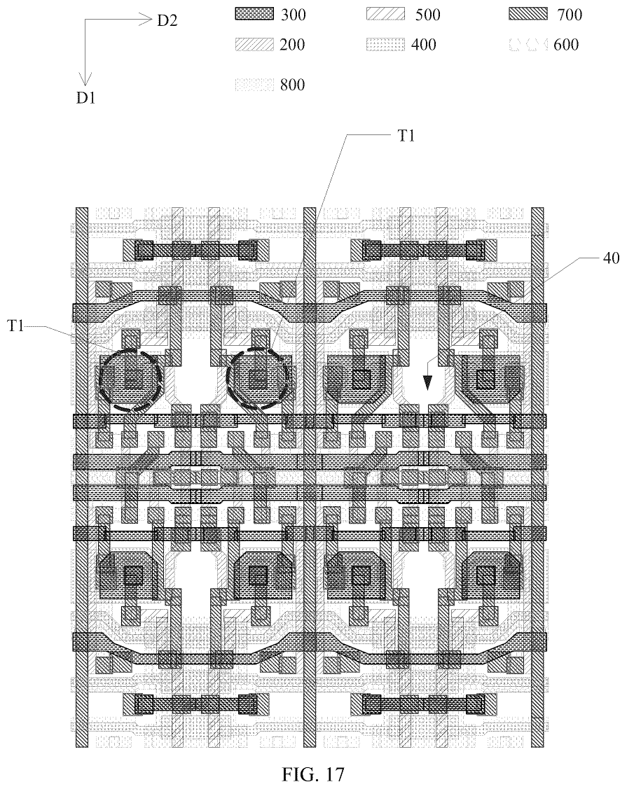

Therefore, in some possible implementations, a light-leakage gap 40 may be provided in the array substrate according to the present embodiment. Exemplarily, referring to FIG. 17, in the second direction D2, the light-leakage gap 40 is disposed between two driving transistors T1 (i.e., as shown by the dashed box in FIG. 14) of two driving units which are adjacent and respectively belong to different second driving unit groups 20. That is, an orthographic projection of the light-leakage gap 40 on the substrate 100 does not overlap with an orthographic projection of the wires in any film layers on the substrate 100. Therefore, the wires in each film layer will not block the light passing through the light-leakage gap 40, so that overall light-transmittance of the array substrate may be improved, thereby improving an acquisition effect of an under-screen optical acquisition device arranged below the display panel.

The present disclosure further provides a display panel, and the display panel includes an array substrate provided by the present disclosure.

In some possible implementations, the display panel may further include a light-emitting layer located on a side of the array substrate. The light-emitting layer may include several film layer structures such as a pixel defining layer, a light-emitting material layer, a cathode layer and an encapsulation layer, which will not be described here.

In another possible implementation, the display panel may further include a light-emitting layer located on a side of the array substrate, which may include several film layer structures such as a pixel defining layer, an isolation structure, a light-emitting material layer, a cathode layer, an encapsulation layer. Therein, patents including No. PCT/CN2023/134518, No. 202310759370.2, No. 202310740412.8, No. 202310707209.0, and No. 202311346196.5 record relevant technical solutions of the isolation structure, and their contents are incorporated herein by reference into the present disclosure for reference, and will not be described in this embodiment again.

The present disclosure further provides an electronic device, and the electronic device includes a display panel provided by the present disclosure. The electronic device may include a mobile phone, a tablet, a smart wearable device, a television, a laptop, a monitor, and other devices with display functions.

In conclusion, the present disclosure provides an array substrate, a display panel, and an electronic device. Two driving units, adjacent in the first direction, in the array substrate are configured to share the first scan wire and the second scan wire, so that the semiconductor wiring segment in the driving unit may extend along a straight line and overlap with the first scan wire and the second scan wire to form a first switching transistor and a second switching transistor respectively, thereby reducing a space occupied by the semiconductor wiring segment.

The embodiments mentioned above merely represent several implementations of the present disclosure, although the descriptions are relatively specific and detailed, they should not be construed as a limitation on the scope of the invention patent. It should be noted that for those skilled in the art, several modifications and improvements can still be made without departing from the concept of the present disclosure, and these should fall within the protection scope of the present disclosure. Therefore, the protection scope of the present invention patent should be determined by the appended claims.

What is claimed is:

1. An array substrate, comprising:
a substrate;
a first semiconductor layer located on a side of the substrate, wherein the first semiconductor layer comprises a first semiconductor wiring segment and a second semiconductor wiring segment, and the first semiconductor wiring segment and the second semiconductor wiring segment extend side by side in a first direction;
a first conductive layer located on a side, away from the substrate, of the first semiconductor layer, wherein the first conductive layer comprises a first scan wire and a second scan wire, the first scan wire and the second scan wire extend side by side in a second direction, and the first direction intersects with the second direction;
a plurality of driving units, wherein the plurality of driving units comprise a first driving unit and a second driving unit adjacent in the first direction;
in the first direction, the first driving unit is located on a side, away from the second scan wire, of the first scan wire, and the second driving unit is located on a side, away from the first scan wire, of the second scan wire;
the first driving unit comprises a first switching transistor and a second switching transistor; an orthographic projection of the first semiconductor wiring segment on the substrate at least partially overlaps with orthographic projections of the first scan wire and the second scan wire on the substrate separately, the first switching transistor and the second switching transistor of the first driving unit are respectively located at a position of the orthographic projection of the first semiconductor wiring segment on the substrate overlapping with the orthographic projection of the first scan wire on the substrate, and a position of the orthographic projection of the first semiconductor wiring segment on the substrate overlapping with the orthographic projection of the second scan wire on the substrate; and
the second driving unit comprises a first switching transistor and a second switching transistor;
an orthographic projection of the second semiconductor wiring segment on the substrate at least partially overlaps with the orthographic projections of the first scan wire and the second scan wire on the substrate separately, the first switching transistor and the second switching transistor of the second driving unit are respectively located at a position of the orthographic projection of the second semiconductor wiring segment on the substrate overlapping with the orthographic projection of the first scan wire on the substrate, and a position of the orthographic projection of the second semiconductor wiring segment on the substrate overlapping with the orthographic projection of the second scan wire on the substrate.

2. The array substrate according to claim 1, wherein the first semiconductor layer further comprises a third semiconductor wiring segment corresponding to other transistors in the first driving unit except for the first switching transistor and the second switching transistor in the first driving unit, and a fourth semiconductor wiring segment corresponding to other transistors in the second driving unit except for the first switching transistor and the second switching transistor in the second driving unit; and the third semiconductor wiring segment and the fourth semiconductor wiring segment are symmetrically disposed relative to an axis extending in the second direction; and
an orthographic projection of the axis on the substrate is located between the orthographic projections of the first scan wire and the second scan wire on the substrate.

3. The array substrate according to claim 1, wherein the driving unit further comprises a driving transistor; the first semiconductor layer further comprises a third semiconductor wiring segment, corresponding to other transistors in the first driving unit except for the first switching transistor, the second switching transistor and the driving transistor in the first driving unit, and further comprises a fourth semiconductor wiring segment, corresponding to other transistors in the second driving unit except for the first switching transistor, the second switching transistor and the driving transistor in the second driving unit; and the third semiconductor wiring segment and the fourth semiconductor wiring segment are symmetrically disposed relative to an axis extending in the second direction;
an orthographic projection of the axis on the substrate is located between the orthographic projections of the first scan wire and the second scan wire on the substrate;
semiconductor wiring segments corresponding to the driving transistor are asymmetrically disposed relative to the axis extending in the second direction.

4. The array substrate according to claim 1, further comprising a first initialization wire extending in the second direction, wherein an orthographic projection of the first initialization wire on the substrate is located between the orthographic projections of the first scan wire and the second scan wire on the substrate; and
the driving unit comprises a driving transistor; the first driving unit and the second driving unit share the first initialization wire, and the first initialization wire is configured to provide first initialization voltage for a first electrode of a driving transistor of the first driving unit and a first electrode of a driving transistor of the second driving unit.

5. The array substrate according to claim 4, wherein the first scan wire and the second scan wire synchronously transmit a same scan signal; the first switching transistor and the second switching transistor are connected in series between the first electrode of the driving transistor and the first initialization wire, and the first switching transistor and the second switching transistor are configured to provide voltage initialization control on the first electrode of the driving transistor.

6. The array substrate according to claim 4, further comprising a fifth conductive layer located on a side, away from the substrate, of the first conductive layer, wherein the first initialization wire is located in the fifth conductive layer;
a material of the first conductive layer comprises a metal material;
a material of the fifth conductive layer comprises a metal material.

7. The array substrate according to claim 4, further comprising a fourth conductive layer, wherein the fourth conductive layer comprises a first connection wiring segment.

8. The array substrate according to claim 4, wherein the driving transistor of the first driving unit is located on the side, away from the second scan wire, of the first scan wire, and the driving transistor of the second driving unit is located on the side, away from the first scan wire, of the second scan wire;
an end, close to the first scan wire, of the first semiconductor wiring segment is connected to the first electrode of the driving transistor of the first driving unit through the first connection wiring segment, and an end, close to the second scan wire, of the first semiconductor wiring segment is connected to the first initialization wire through the first connection wiring segment; and
an end, close to the second scan wire, of the second semiconductor wiring segment is connected to the first electrode of the driving transistor of the second driving unit through the first connection wiring segment, and an end, close to the first scan wire, of the second semiconductor wiring segment is connected to the first initialization wire through the first connection wiring segment.

9. The array substrate according to claim 1, further comprising a second initialization wire extending in the second direction, wherein an orthographic projection of the second initialization wire on the substrate is located between the orthographic projections of the first scan wire and the second scan wire on the substrate; and
the driving unit further comprises a pixel electrode connection point, the first driving unit and the second driving unit share the second initialization wire, and the second initialization wire is configured to provide second initialization voltage for a pixel electrode connection point of the first driving unit and a pixel electrode connection point of the second driving unit.

10. The array substrate according to claim 9, further comprising a third conductive layer and a fourth conductive layer located on a side, away from the substrate, of the first conductive layer, wherein the second initialization wire comprises a first portion and a second portion, the first portion is located in the third conductive layer and the second portion is located in the fourth conductive layer, and the first portion and the second portion are alternately disposed in the second direction; and
at least one of a material of the third conductive layer and a material of the fourth conductive layer comprises a metal material.

11. The array substrate according to claim 9, wherein the driving unit comprises a third switching transistor, the third switching transistor is connected to the pixel electrode connection point and the second initialization wire respectively, and the third switching transistor is configured to provide voltage initialization control on the pixel electrode connection point.

12. The array substrate according to claim 1, further comprising a second conductive layer, a second semiconductor layer, a third conductive layer, a fourth conductive layer, and a fifth conductive layer sequentially located on a side, away from the substrate, of the first conductive layer; and
further comprising a first insulation layer located between the first semiconductor layer and the first conductive layer, a second insulation layer located between the first conductive layer and the second conductive layer, a third insulation layer located between the second conductive layer and the second semiconductor layer, a fourth insulation layer located between the second semiconductor layer and the third conductive layer, a fifth insulation layer located between the third conductive layer and the fourth conductive layer, and a sixth insulation layer located between the fourth conductive layer and the fifth conductive layer.

13. The array substrate according to claim 1, further comprising a plurality of first driving unit groups, wherein each of the plurality of first driving unit groups comprises a first driving unit and a second driving unit; and the first driving unit and the second driving unit in a same first driving unit group share the first scan wire and the second scan wire.

14. The array substrate according to claim 13, further comprising a third initialization wire; wherein in the first direction, an orthographic projection of the third initialization wire on the substrate is located between two adjacent first driving unit groups; and a first driving unit and a second driving unit, being adjacent in the first direction and respectively belonging to different first driving unit groups, share the third initialization wire.

15. The array substrate according to claim 14, wherein the driving unit comprises a driving transistor, and the third initialization wire is configured to provide third initialization voltage for an electrode of the driving transistor.

16. The array substrate according to claim 15, further comprising a fourth conductive layer and a fifth conductive layer located on a side, away from the substrate, of the first conductive layer, wherein
the third initialization wire comprises a third portion and a fourth portion, the third portion is located in at least one of: the first conductive layer and the fourth conductive layer, the fourth portion is located in the fifth conductive layer, the third portion and the fourth portion are alternately disposed in the second direction, and the fourth portion comprises a light-transmitting hollow region.

17. The array substrate according to claim 15, wherein the driving unit comprises a fourth switching transistor and a fifth switching transistor; the fourth switching transistor and the fifth switching transistor are connected between the electrode of the driving transistor and the third initialization wire, and the fourth switching transistor and the fifth switching transistor are configured to provide voltage initialization control on the electrode of the driving transistor.

18. The array substrate according to claim 1, further comprising a plurality of fourth initialization wire extending in the second direction;
a plurality of second driving unit groups, wherein each of the plurality of second driving unit groups comprises two driving units adjacent in the second direction;
two driving units in a same second driving unit group are symmetrically disposed relative to the fourth initialization wire; and
a light-leakage gap is provided between driving transistors of two driving units being adjacent in the second direction and respectively belonging to different second driving unit groups.

19. A display panel, comprising the array substrate according to claim 1.

20. An electronic device, comprising the display panel according to claim 19.
